(19) United States
(12) Patent Application Publication
(10) Pub. No.: US 2007/0179719 A1
(43) Pub. Date: Aug. 2, 2007

(54) Circuit arrangement for the overload protection of a controllable switching event

(75) Inventor: Thomas Dorner, Schnaittach (DE)

Correspondence Address: CONTINENTAL TEVES, INC., ONE CONTINENTAL DRIVE, AUBURN HILLLS, MI, 48326-1581, US

(73) Assignee: Conti Temic Microelectronic, GMBN

(21) Appl. No.: 10/589,475

(22) PCT Filed: Jan. 29, 2005
(86) PCT No.: PCT/DE05/00136

§ 371 Date: Aug. 14, 2006

(30) Foreign Application Priority Data
Feb. 14, 2004 (DE) 10 2004 007 288.4

(51) Int. Cl. G01R 31/00; G06F 19/00

(52) U.S. Cl. 702/58

(57) ABSTRACT

Disclosed is a circuit arrangement (200) for protecting a switching element (T20) from overload when activated, the switching element is connected between an electrical consumer (L1) and a supply voltage (UV) and controlled by a control signal (ST20, ST20′). The circuit arrangement has evaluation elements (60) for determining a malfunction from a switching element voltage (U20) that falls across the activated switching element (T20), a memory (80) for storing malfunction information and for generating a malfunction signal (FS20), in addition to a feedback element (90) for taking into consideration the malfunction signal (FS20) during the control of the switching element (T20) by the control signal (ST20′). The memory (80) and the feedback element (90) are configured with a reference to ground.

### BACKGROUND OF THE INVENTION

The invention relates to a circuit arrangement for protecting a switching element from overload when activated, said element being connected between an electrical consumer and a supply voltage, and being controlled by a control signal.

Usually, an electrical consumer can be disconnected from the electrical supply voltage provided in order to supply electrical energy by means of a switching element. Here, it is generally possible to arrange the switching element on the high side, i.e. between the electrical supply voltage and the consumer, or on the low side, i.e. between the electrical consumer and the reference potential (=ground). In both cases, the current flow is interrupted by the electrical consumer when the switching element is opened.

An example for an application of this type is the control of a brushless, electronically commutated direct current motor (=BLDC motor or EC motor) using a converter switch, in which a total of six switching elements are provided, each of which takes the form of a MOSFET semi-conductor switch in a three-phase bridge connection (=the so-called B6 bridge). Each of the total of three motor strands is connected via two of these switching elements to the supply and the reference potential, so that three switching elements are arranged on the high side, and the other three switching elements are arranged on the low side. Now, during motor operation, depending on the current point of observation, either two motor strands are connected to the supply potential and one motor strand is connected to the reference potential, or one motor strand is connected to the supply potential and two motor strands are connected to the reference potential, or one motor strand is connected to the supply potential and one motor strand is connected to the reference potential. This results in a current flow at any point in time in the three strand inductivities of the direct current motor when activated.

When activated, a power dissipation occurs in the switching element, which is calculated from the product of the switching element voltage which is present between the two main connections of the switching element and the current which flows through the switching element. For certain applications, it is desirable that this power dissipation be monitored, in order to prevent a thermal destruction of the switching element. This danger arises in particular when a short-circuit with the supply or reference potential occurs in a motor strand. Then the current in the defective motor strand, and therefore also in at least one of the switching elements via which this motor strand is connected, would adopt a very high value. Since the current flow and the voltage drop are linked with each other via the ON resistance of the switching element, this also results in a sharp increase in the related switching element voltage.

Consequently, the power dissipation can be checked based on the switching element voltage. If the switching element voltage, and therefore also the power dissipation, exceeds a specified limit value, the switching element should be switched off very quickly, in order to protect it from being destroyed. Circuit arrangements are known for overload protection for switching elements which are arranged on the low side. Both these circuit arrangements for overload protection and the control switching of the switching element arranged on the low side are configured with a reference to ground. This means that the input and output signals of the circuits and also at least one large part of the circuit potential which is defined within the circuit arrangements are related to the reference potential. As a result, a relatively simple circuit can be realised.

Furthermore, circuit arrangements for overload protection of a switching element arranged on the high side are known. An example is described in U.S. Pat. No. 5,923,210. However, these circuit arrangements for overload protection, together with the control circuit of the switching element are configured essentially with a reference to the supply potential. This means that the input and output signals, as well as at least a large part of the circuit potential defined within the circuit arrangements, are related to the supply potential. The switching element voltage, in particular the voltage present on the switching element, thus also comprises a reference to the supply potential. The recording and evaluation of a potential-related signal does however entail an increase in circuit complexity.

A power module is known from US 2002/0039269 A1which comprises a circuit arrangement for the overload protection of a switching element which arranged on the high side, wherein the circuit arrangement comprises a memory means, feedback means and evaluation elements, which are related to the different potentials.

The object of the invention is now to provide a circuit arrangement for protecting a switching element from overload when activated, said element being connected between an electrical consumer and a supply voltage, and being controlled by a control signal, which can be realised with a comparatively simple circuit.

### SUMMARY OF THE INVENTION

The circuit arrangement according to the invention for protecting a switching element from overload when activated, said element being connected between an electrical consumer and a supply voltage, and being controlled by a control signal, comprises at least
evaluation elements for determining a malfunction by means of a switching element voltage that falls across the activated switching element;
memory means for storing malfunction information and for generating a malfunction signal; and
feedback means for taking into consideration the malfunction signal during the control of the switching element by means of the control signal; wherein
the evaluation elements, the memory means and the feedback means are configured with a reference to ground.

Here, the invention is based on the knowledge that the circuit can be realised significantly more simply when the circuit arrangement is designed to a large extent not using the otherwise common supply voltage reference, but using ground reference. It is thus advantageous from a realisation point of view to design both the memory and feedback means with a reference to ground. In order to be able to extend the advantageous ground reference to the largest possible parts of the circuit arrangement, it is particularly advantageous, with reference to the signal response, to alter the level of the supply voltage reference to a ground reference as soon as possible after recording the switching element voltage to be monitored. On the other hand, it is accordingly also advantageous to alter the level back to the supply voltage reference only as late as possible before the switching element is actually controlled. In this way, a large part of the circuit arrangement can be realised with a reference to ground, thus reducing the complexity.

This principle can in general be used for different embodiments of the switching element. It can be applied both with a semi-conductor switching element, such as one in the form of a MOSFET switch, as well as with a controllable electromechanical switching element, for example in the form of a relay switch. Other switching elements are equally possible. Overall, a cost-effective protection function in relation to an overload when the switching element is activated can be realised.

One variant is advantageous wherein the memory means comprise a comparator. In particular, a hysteresis switch is provided on a first comparator input, for example on the plus input of the comparator. This results in the attainment, in a similar manner to the so-called Schmitt trigger, of an upper and a lower hysteresis threshold voltage. Both threshold voltages are here advantageously related to the reference potential (=ground). The malfunction information is stored in the currently valid hysteresis threshold voltage. When the switching element to be monitored is activated and the upper hysteresis threshold voltage is therefore present, for example, on the first comparator input, this indicates an error-free operating state. In reverse, the lower hysteresis threshold voltage on the first comparator input indicates that a malfunction has occurred.

It is advantageous when the feedback means take the form of a release unit. It is particularly simple to realise the release unit as an AND gate. It is equally advantageous when the release unit comprises ground-related input signals and a ground-related output signal. On a first release input, the control signal delivered by a control unit can be applied, and a malfunction signal generated by the memory means can be applied to a second release input. Depending on the state of both input signals, the release unit then delivers an output signal for forwarding to a control connection in the switching element. Generally, it is also possible to design the feedback means without a separate release unit. The feedback of the malfunction signal generated by the memory means is then achieved via the control unit itself. The information content of the malfunction signal is then also taken into account when the control signal is generated by the control unit.

In a further embodiment, the switching element voltage to be monitored is recorded using a measuring element. At least when a malfunction occurs, the switching element voltage is also present as the measurement voltage on this measuring device, which is switched between a main connection of an auxiliary transistor and the supply voltage. Here, a control connection on the auxiliary transistor is also connected to the circuit node, in particular via a decoupling diode, on which the switching element to be monitored and the consumer are interconnected.

It is advantageous to design the measuring element as a measuring resistance. The measurement voltage which is present then consistently follows the switching element voltage—regardless of whether a malfunction has occurred or not. The measurement voltage which corresponds to the switching element voltage then creates, e.g. via current mirroring, a proportionate voltage share of a comparative voltage which is present on a second comparator, for example on the minus input. This comparative voltage is compared by the comparator with the hysteresis threshold voltage which is currently present on the first comparator input. If the result of this comparison shows that the comparative voltage is higher than the upper hysteresis threshold voltage, a malfunction has occurred and the memory means are requested to store the appropriate malfunction information, in particular in the form of the lower hysteresis threshold voltage, and also to generate a corresponding malfunction signal. The decision as to whether a malfunction has occurred is then also made in the comparator. Accordingly, the comparator fulfils a dual function in this version. It is a part of both the memory means and the evaluation elements. The signals to the comparator inputs and on the comparator output are in particular ground-related, so that in this version, the evaluation elements are also configured advantageously with a reference to ground.

In another embodiment, the measuring element contains at least one measuring diode. This measuring element has a diode threshold voltage, from which a current flow is possible over the measuring diode. The measuring diode can be designed as a simple PN diode, in particular from the semi-conducting material silicon. The diode threshold voltage is then the same as the diode breaking voltage, which is typically at approximately 0.7 V for silicon. A higher diode threshold voltage can be achieved in a simple manner by connecting several silicon PN diodes of this type one after the other to a shared measuring element. The value of the diode threshold voltage can be also influenced via the semi-conductor material selected. Alternatively a Zener diode can also be used. The so-called Zener voltage can be set over a certain voltage range.

According to a variant, the measuring diode is in particular part of a level sub-unit in the evaluation elements. In the level sub-unit, a comparison is made between the switching element voltage present on the switching element to be monitored and the diode threshold voltage. The diode threshold voltage is in particular higher than the values of the switching element voltage, which are reached in the normal, i.e. error-free operating state of the activated switching element. If the switching element voltage increases, causing the measurement voltage present on at least one measuring diode to increase above the value of the diode threshold voltage, the auxiliary transistor connects through. The current which flows over the auxiliary transistor is then incorporated for further evaluation. For this variant, the malfunction detection is therefore conducted, at least with respect to the amplitude of the switching element voltage, very close to the switching element to be monitored.

A further possible version is also advantageous, in which the time duration of the too-high value of the switching element voltage or the measurement voltage is also recorded and evaluated. This prevents a malfunction signal from being generated even when the switching element is overloaded only very briefly, and thus with an uncritical overload, and as a result, the switching element from being switched off. This time aspect of the evaluation is conducted in a time sub-unit in the evaluation elements. The time sub-unit contains in particular an RC element with a typical time constant, which can be set using an RC element resistance and an RC element capacity. The RC element capacity is reloaded if a malfunction occurs. This loading procedure lasts for a specific period of time. It is only continued until the end if a malfunction, and therefore an overload of the switching element, is present continuously, and not only for a brief period. Therefore, if the measurement voltage present on at least one measuring diode is higher than the diode threshold voltage for too long (=the duration of the reloading procedure), the time sub-unit causes the memory means to store the malfunction information and to generate the malfunction signal.

Preferred exemplary embodiments will now be explained with reference to the drawing. For clarification purposes, the drawing is not shown to scale, and certain aspects are only shown schematically.

### BRIEF DESCRIPTION OF THE DRAWINGS

In the individual drawings:

FIG. 1 shows a motor which is connected in each case with three switching elements on the low side and high side, wherein the switching elements on the high side are equipped with protective circuits

FIG. 2 shows a first embodiment of one of the protective circuits according to FIG. 1 in a schematic drawing

FIG. 3 shows a second embodiment of one of the protective circuits according to FIG. 1 in a schematic drawing

FIG. 4 shows a realisation of a circuit of the first embodiment according to FIG. 2, and

FIG. 5 shows a realisation of a circuit of the second embodiment according to FIG. 3

### DETAILED DESCRIPTION OF THE DRAWINGS

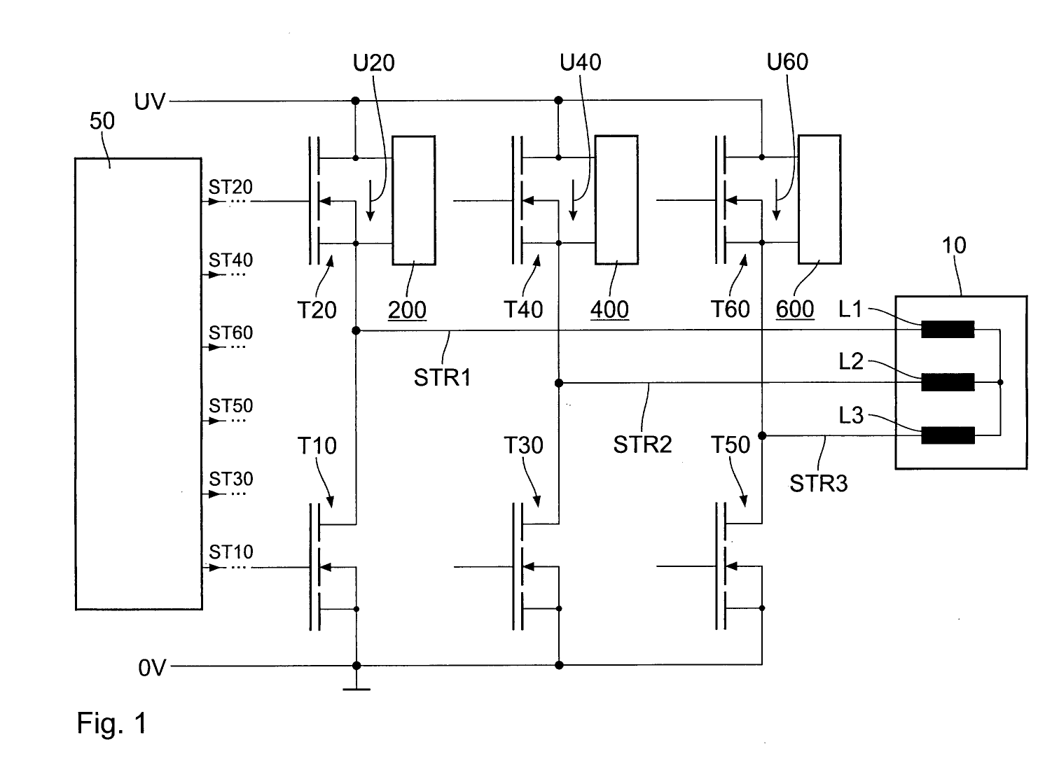

Parts which correspond to each other are labelled with the same reference numerals in FIGS. 1 to 5.

FIG. 1 shows the connection of an electrical consumer in the form of a three-phase, brushless electronically commuted direct current motor 10, which in each case comprises in its three motor strands STR1, STR2 and STR3 one motor strand coil with the related strand inductivity L1, L2 and L3. The three motor strands STR1, STR2 and STR3 are connected via a total of six switching elements T10, T20, T30, T40, T50 and T60 to an electrical supply voltage UV and to the reference potential (=ground=0V). The switching elements T10 to T60 are arranged in a so-called B6 bridge circuit, as is common in a converter or rectifier circuit. They can be controlled via control signals ST10, ST20, ST30, ST40, ST50 and ST60 which are provided by a control unit 50, i.e. they can be activated or off. The switching elements T10 to T60 are in the embodiment shown in FIG. 1 in each case designed as a semi-conductor switch in the form of a MOSFET transistor switch.

During the operation of the motor 10, at each point in time, tow or three of the total of six switching elements T10 to T60 are activated, so that at all times, a conductive connection is present between the electrical supply voltage UV over the motor 10 to the ground potential. When activated, the switching elements T10 to T60 comprise a relatively low, but ultimate ON resistance. Thus, a power dissipation also arises, which may lead, when the increase is too high, to the destruction of the relevant switching element T10 to T60. In order to prevent this from happening, it is advantageous to provide protective circuits for monitoring the power dissipation which arises in the switching elements T10 to T60.

The power dissipation can in particular reach a level which is too high when a malfunction occurs, for example in the form of a short-circuit to the power or reference potential in one of the motor strands STR1 to STR3. This also leads to a steep current increase in those switching elements T10 to T60 via which the defective motor strand STR1 to STR3 is connected to the supply voltage UV or to ground. This steep current increase leads to an increase in the switching element voltage U20, U40 or U60 which falls between the main connections on the affected switching element T10 to T60. The switching element voltage U20, U40 of U60 is a product of the current which flows in the relevant switching element T20, T40 or T60 with the current ON resistance. As a result, the switching element voltage U20, U40 or U60 can be incorporated as a nominal value for the purpose of monitoring the malfunction.

In particular, protective circuits for monitoring the switching elements T10, T30 and T50 which are arranged on the ground side are relatively simple to realise. This is due to the given ground reference, which can also be used for the circuit realisation of the respective protection circuits. This means that the signals provided in the respective protection circuit can in each case be related to the ground potential.

By contrast, the switching elements T20, T40 and T60 are not connected to ground, but to the supply voltage UV. A ground reference is not given for the switching elements T20, T40 and T60. Accordingly, the protective circuits 200, 400 and 600 are more complex for these switching elements T20, T40 and T60 in terms of their circuit realisation. At least in the parts which are close to the switching elements of these protective circuits 200, 400 and 600, a supply voltage reference is present.

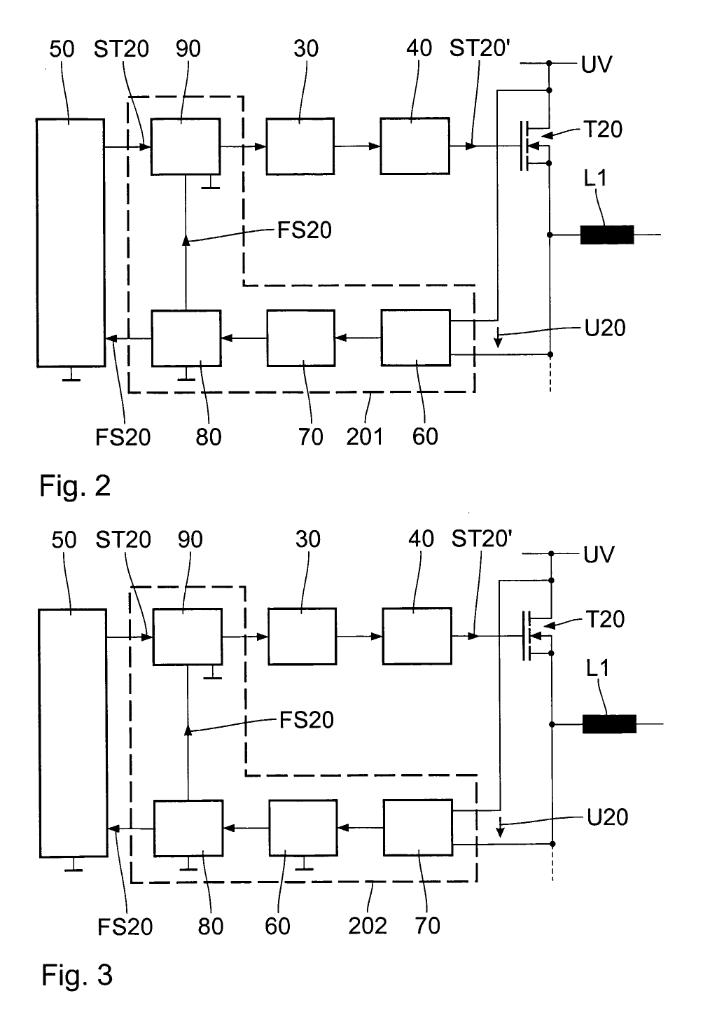

With the example of the protective circuit 200 for the switching element T20 arranged on the high side, two exemplary embodiments of protective circuits 201 and 202 are shown in FIGS. 2 and 3, for which the complexity of the circuit realisation can, however, be kept at an acceptable level.

In the first exemplary embodiment according to FIG. 2, the protective circuit 201 comprises an evaluation unit 60, a level converter 70, a malfunction memory 80 and a release unit 90. In the evaluation unit 60, it is determined whether the switching element voltage U20 adopts a value which is too high, i.e. which indicates a malfunction. This evaluation is still completed with reference to the supply voltage. Using the level converter 70, a transformation then takes place from the reference to the ground potential, so that in the following units, i.e. the malfunction memory 80 and the release unit 90, it is possible to work with a reference to ground in each case.

Depending on the result determined in the evaluation unit 60, malfunction information is stored in the malfunction memory 80, and a malfunction signal FS20 is generated. The malfunction signal FS20 is forwarded both to the control unit 50 and to the release unit 90. This signal is in particular a digital signal which is ground-related. In the release unit 90, the malfunction signal FS20 is linked with the digital control signal ST20 which is provided by the control unit 50 and which is in particular also ground-related. The link is preferably achieved using an AND gate. The result of the AND link is transferred via a further level converter 30 and a drive unit 40 as a modified control signal T20′ to a control connection in the switching element T20 which is not shown in greater detail.

In the second exemplary embodiment according to FIG. 3, another protective circuit 202 is shown, which essentially compiled from the same part components as the protective circuit 201. The main difference consists in the sequence of level conversion and evaluation. With the protective circuit 202, a level conversion is first completed using a level converter 70, with the evaluation only following subsequently. As a result, the evaluation unit 60 can also be configured with a very advantageous ground reference in terms of the circuit realisation. The ground reference is indicated schematically by a ground symbol in FIGS. 2 and 3 on the affected units.

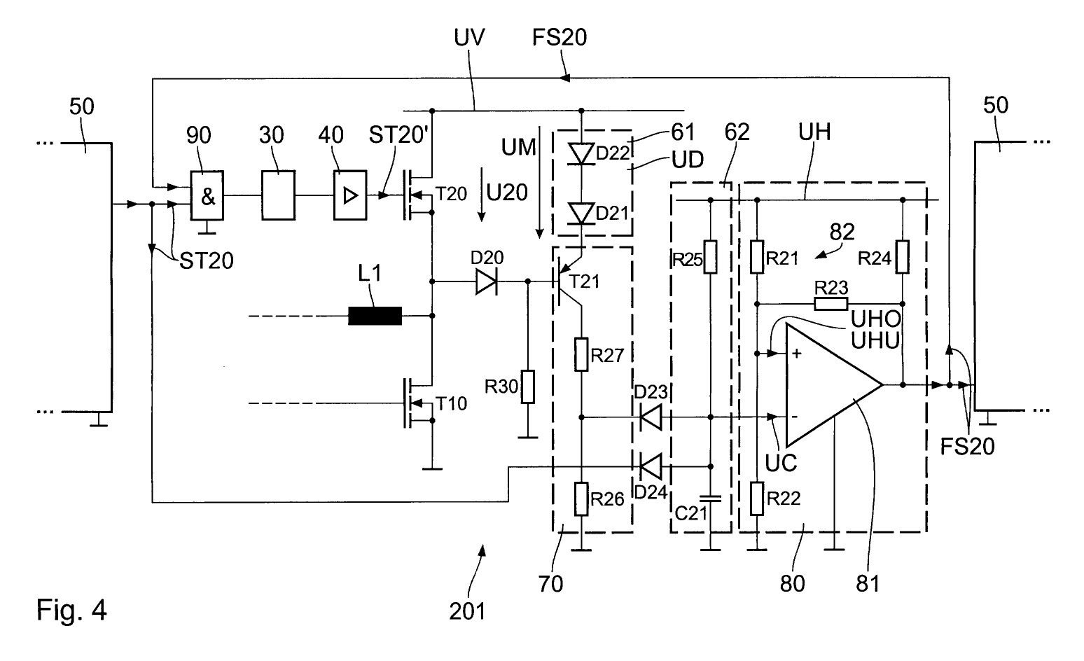

FIG. 4 shows an example for a circuit realisation for the protective circuit 201. At a connection node not shown in greater detail, to which the switching element T20 is connected with its source connection to the strand inductivity L1 of the motor 10, an auxiliary transistor T21 is connected via a decoupling switch consisting of decoupling diode D20 and a decoupling and a bias resistance R30 with its control connection. The auxiliary transistor T21 is in the exemplary embodiment a bipolar PNP transistor. Its control connection is formed from the basic connection. The emitter connection of the auxiliary transistor T21 is connected to the electrical supply voltage UV via a measuring element in the form of two measuring diodes D21 and D22 which are activated behind the other. The collector connection of the auxiliary transistor T21 is guided to the ground via an optional resistance R27 and a collector resistance R26.

The two measuring diodes D21 and D22 are an integral part of the evaluation unit 60 and form a level sub-unit 61. They comprise a diode threshold voltage DU according to the total of their two construction element-specific diode breaking voltages. In the exemplary embodiment, both measuring diodes D21 and D22 are designed as silicon PN diodes, which accordingly comprise in each case a diode breaking voltage of approximately 0.7 V. The auxiliary transistor T21 now remains blocked until the switching element voltage U20 which falls across the activated switching element T20 produces a measurement voltage UM on the two measuring diodes D21 and D22 which is larger than the diode threshold voltage UD. The auxiliary transistor T21 is then connected through and the measurement voltage UM has approximately the same value as the switching element voltage U20, since the diode breaking voltage of the coupling diode D20 approximately levels with the basic emitter voltage of the basic emitter diode of the auxiliary transistor D21. The diodes D20 of the auxiliary transistor T21 are also designed in the example as silicon components.

The decision as to whether the level of power dissipation created in the switching element T20 is too high results therefore from a comparison of the switching element voltage U20 with the diode threshold voltage UD. The latter can be varied by switching additional measuring diodes one after the other. Furthermore, the measuring element can also be designed as a Zener diode, which is then switched, however, with a reverse polarity compared to the measuring diodes D21 and D22 between the emitter connection of the auxiliary transistor T21 and the supply voltage UV. The diode threshold voltage which determines the maximum permitted value for the switching element voltage U20 would then by specified by the so-called Zener voltage, which comprises a fixed value which can however be varied to a certain degree via the type of Zener diode selected. The diode threshold voltage UD can therefore be well adapted to the required maximum permitted value of the switching element voltage.

If according to the determination in the level unit 60, the value of the switching element voltage U20 lies above the maximum permitted threshold value (=diode threshold value UD), a current flows over the two main connections, i.e. the emitter and collector connection, of the auxiliary transistor T21. This current also flows over the collector resistance R26 and produces a voltage drop there which indicates this malfunction. The voltage on the collector resistance R26 is here related to the ground in particular. It is incorporated for further evaluation, and in particular also for malfunction storage. The auxiliary transistor T21 and the collector resistance R26 therefore convert the supply voltage related measurement voltage UM on the measuring diodes D21 and D22 into a voltage signal which is present on the collector resistance R26 and which is ground-related in particular. Both components can therefore be interpreted as integral parts of the level converter 70. This is indicated in the example shown in FIG. 4 by a dotted border.

The connection side of the collector resistance R26 which faces away from the ground potential is connected via a coupling diode D23 with a time sub-unit 62, which is also an integral part of the evaluation unit 60. In the time sub-unit 62, a determination is made as to whether the voltage value which is too high in the switching element voltage U20 has been present for a longer period of time. Only then is it assumed that a malfunction has occurred which may put at risk the switching element T20 to be monitored. By contrast, very brief overvoltages on the switching element T20 are not shown. The time sub-unit 61 comprises an RC member which is switched between an auxiliary voltage UH and ground with a series connection of an RC member resistance R25 and an RC member capacity C21. The coupling diode D23 is connected with its anode connection to the connection node between the RC member resistance R25 arranged on the high side and the RC member capacity C21 arranged on the low side.

If the potential on the cathode connection of the coupling diode D23 increases due to the current flow through the collector resistance R26, the voltage conditions in the RC member change, and the RC member capacity C21 is reloaded with the time constant τ=R25×C21, insofar as the switching element voltage U20 lies above the maximum permitted value, i.e. the diode threshold voltage DU, during this time period.

The voltage which falls across the RC member capacity C21, which is in turn in particular ground-related, is fed as a comparative voltage UC to the malfunction memory 80. The malfunction memory 80 contains as its main component a comparator 81 which is also driven on the auxiliary voltage UH, with a positive and a negative input. The positive input is connected with an already known hysteresis circuit 81 consisting of hysteresis resistances R21, R22, R23 and R24. The comparative voltage UC is fed to the negative comparator input and compared by the comparator 81 with the voltage level currently present on the comparator input. Depending on the result of this comparison, the digital malfunction signal FS20 is generated on the output of the comparator 81.

The potential on the positive comparator input can only adopt two stable states, depending on the hysteresis circuit 82. This is a lower and an upper hysteresis threshold voltage UHU or UHO. These two potential values are also used for malfunction storage. If the lower hysteresis threshold voltage UHU is present on the positive comparator input, this is a sign that a malfunction has occurred. And in reverse, the upper hysteresis threshold voltage UHO indicates an error-free state.

In the example according to FIG. 4, the auxiliary voltage UH has a value of 5 V and the upper and lower hysteresis threshold voltage UHU and UHO has a value of 1 V and 4 V. Generally, however, other voltage values can be selected. By contrast, the value of the supply voltage UV is higher. In this way, the supply voltage UV comprises, for example, a value which is standard for a vehicle electrical system of 12 V or 42 V when applied in motor vehicles. Generally, however significantly higher voltage values of several 100 V and even up to 1000 V are also possible for the supply voltage UV.

The functional principle of the circuit arrangement described in FIG. 4 will now be explained in greater detail. The control unit 50 delivers the control signal ST20 in the form of a ground-related digital signal. When the switching element T20 is switched off, the control signal ST20 adopts the value 0 V. The AND connection on the release unit 90 also delivers 0 V as an output signal, so that the control input of the switching element T20 is delivered a modified control signal ST20′ via the level converter 30 and the driver unit 40, which leaves the switching element T20 either switched off or in an OFF state. The control signal ST20 is also issued via a reset diode D 24 to the negative comparator input of the comparator 81. Due to the diode breaking voltage of the reset diode D24, the comparative voltage UC adopts a value of 0.7 V, which is in particular lower than the two hysteresis threshold voltages UHU and UHO. The voltage on the negative comparator input is therefore then lower than on the positive comparator input, so that the output signal of the comparator 80 adopts the value for the digital “1”, which in the example is the voltage value 5 V. This is delivered back as a malfunction signal FS20 to the control unit 50 and to the release unit 90. At the same time, the hysteresis circuit 82 causes the upper hysteresis threshold voltage UHO (=4 V) to be present on the positive comparator input. When the control signal ST20 adopts the value for switching off the switching element T20, the comparator 80 is thus securely reset, and an error-free state is (again) shown.

If the switching element T20 is to be activated again, the control signal ST20 adopts the value for the digital “1” (=5 V). The connection unit 90 also then delivers a digital “1” and the switching element T20 is activated by the level converter 30 and the driver unit 40. At the same time, the 0.7 V voltage value of the comparative voltage UC which has been present thus far on the negative comparator input is lifted. The RC member capacity C21 is reloaded via the RC member resistance R25 up to a value of:

$${UC}_{∞} = UH \cdot \frac{R 26}{R 25 + R 26} + UD 23 \cdot \frac{R 26}{R 25 + R 26} \qquad ( 1 )$$

wherein the breaking voltage of the coupling diode D23 is labelled DU 23 and the stable end value of the comparative voltage UC is labelled Ucon to which the RC member capacity C21 is loaded when no malfunction has occurred and when the switching element D20 is activated. The voltage value Ucon should here be selected by dimensioning the resistances R25 and R26 accordingly so that it is in particular higher than the lower hysteresis threshold voltage UHU (=1 V) and lower than the upper hysteresis threshold voltage UHO (=4 V). The comparator 80 does not then commutate, and the upper hysteresis threshold voltage UHO which indicates the error-free state continues to be present on its positive comparator input.

If a malfunction occurs during the activated state, the switching element voltage U20 increases to a value above the diode threshold voltage DU, and basic current flows from the PNP auxiliary transistor T21 over the decoupling and bias resistance R30. The auxiliary transistor T21 conducts current and produces the voltage drop already described on the collector resistance R26. The RC member capacity C21 is reloaded. IN particular, when the voltage drop on the collector resistance R26 adopts a value which is higher than (UH−UD23), the current will no longer flow from the RC member resistance R25 over the coupling diode D23 and over the collector resistance R26 to ground. Then, the RC member capacity C21 is finally loaded to the value of the auxiliary voltage UH (=5 V), and the comparative voltage UC on the negative comparator input adopts a higher value than the upper hysteresis threshold voltage UHO which is present on the positive comparator input. The comparator 81 commutates and issues a malfunction signal FS20 with a digital value “0” (=0 V). This error signal FS20 causes the switching element T20 to switch off via the release unit 90, and thus protects it from thermal overload and destruction. At the same time, the value on the positive comparator input is set via the hysteresis circuit 82 to the lower hysteresis threshold voltage UHU (=1 V), which causes the presence of a malfunction to be indicated. The lower hysteresis threshold voltage UHU now remains stored in the malfunction memory 80 until the comparator 81 is reset by the control unit 50 via a switch-off command (=0 V) in the control signal ST20.

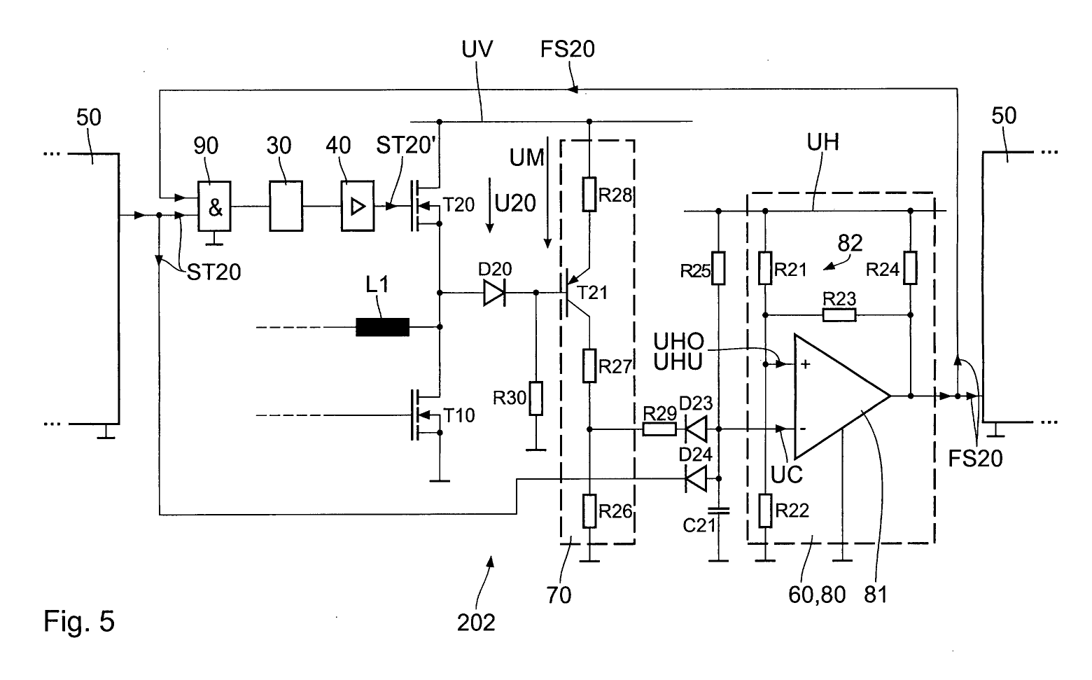

The circuit realisation of the second protective circuit 202 shown in FIG. 5 essentially differs from the protective circuit 201 through the different design of the measuring element. Instead of the two measuring diodes D21 and D22, the protective circuit 202 is given a measuring resistance R28, across which the measurement voltage UM drops. This difference, which at first glance is only insignificant, leads however to a different basic means of functioning of the protective circuit 202. The resistance R29 which is additionally provided is merely optional.

The protective circuit 201 functions in a (quasi-) digital manner. Current only flows over the measuring diodes D21 and D22 and the auxiliary transistor T21 when the switching element voltage U20 to be monitored is higher than the maximum permitted value. The key decision criterion for the presence of a malfunction is therefore whether or not the current is flowing over the measuring diodes D21 and D22. In relation to the current flow, this is in principle a digital decision.

By contrast, the protective circuit 202 operates practically in an analogue manner, at least with regard to the current flow over the auxiliary transistor T21. The auxiliary transistor T21 is namely continuously conductive (=interconnected) as long as the switching element voltage U20 is positive, in particular therefore also when there is no malfunction when the switching element T20 is activated. Here, the level of the current value is far more decisive than the fact of the current flow alone.

In a similar manner to a circuit for voltage mirroring, the switching element voltage U20 is impressed as the measurement voltage UM on the measuring resistance R28. The current which flows through the auxiliary transistor T21 generates—as it has already done in the protective circuit 201—a voltage share on the collector resistance R26 which is proportionate to the switching element voltage U20 to be monitored. This voltage share is ground-related, which enables the unit from the measuring resistance R28, the auxiliary transistor R21 and the collector resistance R26 to be interpreted in this second exemplary realisation as the level converter 70.

The RC member capacity C21 is loaded to a value of the comparative voltage UC of:

$$UC = ( U 20 \cdot \frac{R 25 \cdot R 26}{R 28} + UH \cdot ( R 26 + R 29 ) + UD 23 \cdot R 25 ) \cdot \frac{1}{R 25 + R 26 + R 29} \qquad ( 2 )$$

In the equation (2), the share which is created by the switching element voltage U20 to be monitored is easy to recognise (=first addend in the bracket term). If the comparative voltage UC is set at the same level as the upper hysteresis threshold voltage UHO, a maximum permitted value for the switching element voltage U20 can be determined from the equation (2), above which the protective circuit 202 causes the switching element to be monitored T20 to be switched off. The maximum permitted switching element voltage U20 above which the protective circuit is activated depends in particular on the measuring resistance R28. It can therefore also be dimensioned using this resistance value to a required threshold.

Over the optional resistance R27, the measuring range of the switching element voltage U20 can be restricted as required.

If a malfunction occurs, the comparative voltage UC finally increases in relation to the switching element voltage U20 which also increases, until it exceeds the value of the upper hysteresis threshold voltage UHO which is present on the positive comparator input. The comparator 81 then commutates and the switching element T20 is switched off to protect it from overload via the malfunction signal FS20 which is delivered to the release unit 90. With the protective circuit 202, the comparator 81 is therefore simultaneously an integral part of the evaluation unit 60 and of the malfunction memory 80.

The switching operations described are completed with a time delay which is in turn determined by the reloading procedure of the RC member capacity C21, so that when the threshold value for the switching element voltage U20 is only exceeded very briefly, no unnecessary switch off of the switching element T20 results.

Both protective circuits 201 and 202 operate with the circuit realisation with ground-related signal potentials. This leads to a significant reduction in complexity, and has a beneficial effect on costs.

1-9. (canceled)

10. A circuit arrangement for protecting a switching element (T20, T40, T60) from overload when activated, the switching element being connected between an electrical consumer (10, L1, L2, L3) and a supply voltage (UV), and being controlled by a control signal (ST20, ST20′, ST40, ST60), the circuit arrangement comprising:
evaluation elements (60, 61, 62) for determining a malfunction by a switching element voltage (U20, U40, U60) that falls across an activated switching element (T20, T40, T60);
a memory for storing malfunction information (UHU) and for generating a malfunction signal (FS20); and
a feedback element (90) for taking into consideration the malfunction signal (FS20) during control of the switching element (T20) by means of the control signal (ST20′), wherein the evaluation elements (60), the memory and the feedback element (90) are configured with reference to ground.

11. A circuit arrangement according to claim 10, wherein the memory (80) contain a comparator (81), wherein the comparator (81) is connected at a first comparator input to a hysteresis circuit (82), so that an upper and lower hysteresis threshold voltage (UHO and UHU) results which is in each case related to the ground, and the malfunction information is stored in the currently valid hysteresis threshold voltage (UHO, UHU).

12. A circuit arrangement according to claim 10, wherein the feedback element contains a release unit (90) in the form of an AND gate with two ground-related release input signals and a ground-related release output signal.

13. A circuit arrangement according to claim 10, wherein the switching element voltage (U20) is also present, at least when a malfunction occurs, as a measurement voltage (UM) on a measuring element (R28, D21, D22), which is connected between a main connection of an auxiliary transistor (T21) and the supply voltage (UV).

14. A circuit arrangement according to claim 13, wherein the measuring element has a measuring resistance (R28).

15. A circuit arrangement according to claim 13, wherein which the switching element voltage (U20) present on the measuring resistance (R28) is used in determining a comparative voltage (UC) which is present on a second comparator input and which is related to the ground, so that the memory for storing the malfunction information (UHU) and for generating the malfunction signal (FS20) is triggered if the comparative voltage (UC) is higher than the upper hysteresis threshold voltage (UHO).

16. A circuit arrangement according to claim 13, wherein which the measuring element has at least one measuring diode (D21, D22) and one diode threshold voltage (UD).

17. A circuit arrangement according to claim 16, wherein which the evaluation elements (60) contain a level sub-unit (61) which comprises at least one measuring diode (D21, D22), and the auxiliary transistor (T21) interconnects if the measurement voltage (UM) which is present on the at least one measuring diode (D21, D22) is higher than the diode threshold voltage (UD).

18. A circuit arrangement according to claim 16, wherein which the evaluation elements (60) contain a time sub-unit (62) which particularly comprises an RC member, wherein the time sub-unit (62) triggers the memory means (80, 81, 82) to store the malfunction information (UHU) and to generate the malfunction signal (FS20), if the measurement voltage (UM) which is present on the at least one measuring diode (D21, D22) is higher than the diode threshold voltage (UD) for too long a period of time.
